(19) United States
(12) Patent Application Publication
(10) Pub. No.: US 2011/0049605 A1
(43) Pub. Date: Mar. 3, 2011

(54) SPLIT GATE NONVOLATILE SEMICONDUCTOR STORAGE DEVICE AND METHOD OF MANUFACTURING SPLIT GATE NONVOLATILE SEMICONDUCTOR STORAGE DEVICE

(75) Inventor: Hisashi ISHIGURO, Kanagawa (JP)

(73) Assignee: RENESAS ELECTRONICS CORPORATION, Kanagawa (JP)

(21) Appl. No.: 12/848,488

(22) Filed: Aug. 2, 2010

(30) Foreign Application Priority Data
Aug. 28, 2009 (JP) 2009-198311

(51) Int. Cl. H01L 29/788; H01L 21/28

(52) U.S. Cl. 257/316; 438/594; 438/682; 257/E29.3; 257/E21.209; 257/E21.158

(57) ABSTRACT

A split gate nonvolatile semiconductor storage device includes: a substrate; a floating gate; a control gate; a first source/drain diffusion layer; a second source/drain diffusion layer; and a silicide. The floating gate is formed on the substrate through a gate insulating film. The control gate is formed adjacent to the floating gate through a tunnel insulating film. The first source/drain diffusion layer is formed in a surface region of the substrate on a side of the floating gate. The second source/drain diffusion layer is formed in a surface region of the substrate on a side of the control gate. The silicide contacts the first source/drain diffusion layer.

### INCORPORATION BY REFERENCE

This application is based upon and claims the benefit of priority from Japanese patent application No. 2009-198311 filed on Aug. 28, 2009, the disclosure of which is incorporated herein in its entirety by reference.

### BACKGROUND OF THE INVENTION

1. Field of the Invention

The present invention relates to a split gate nonvolatile semiconductor storage device and a method of manufacturing a split gate nonvolatile semiconductor storage device.

2. Description of Related Art

As a nonvolatile semiconductor storage device having a characteristic that stored data is not erased in a case where a power source is shut down, a split gate nonvolatile semiconductor storage device is known (for example, refer to the patent literature 1: U.S. Pat. No. 6,525,371 B2 and the patent literature 2: Japanese Patent Publication No. 2005-268804A (corresponding to U.S. Pat. No. 7,029,974 B2)). FIG. 1 is a cross-sectional view showing a configuration of the split gate nonvolatile semiconductor storage device (hereinafter referred to as a split gate nonvolatile memory) described in the above-mentioned patent literature 1. In the split gate nonvolatile memory described in the patent literature 1, a plurality of storage elements (hereinafter referred to as split gate t nonvolatile memory cells 101) are provided.

As shown in FIG. 1, the split gate nonvolatile memory cell 101 includes a first source/drain diffusion layer 103 and a second source/drain diffusion layer 104. The first source/drain diffusion layer 103 and the second source/drain diffusion layer 104 are formed in a surface region of a substrate 102. In addition, the split gate nonvolatile memory cell 101 includes a floating gate 105 and a control gate 106. The floating gate 105 is provided in an upper layer of the substrate 102 through a gate oxide film 107. In addition, the control gate 106 is provided in the upper layer of the substrate 102 through a tunnel oxide film 108. Moreover, the tunnel oxide film 108 is provided between the floating gate 105 and the control gate 106. A source plug 109 is provided on the first source/drain diffusion layer 103. An acute angle portion is provided to the floating gate 105. In addition, a spacer 111 is provided on the floating gate 105.

Additionally, as described in the patent literature 2, a split gate nonvolatile semiconductor storage device having a split gate nonvolatile memory cell that has a different shape from the above-mentioned split gate nonvolatile memory cell 101 is known.

Referring to drawings, operations of the split gate nonvolatile memory cell 101 described in the patent literature 1 (or the patent literature 2) will be explained. FIGS. 2A to 2B are schematic diagrams showing the operations of the split gate nonvolatile memory cell 101 shown in FIG. 1. FIG. 2A shows a writing operation of the split gate nonvolatile memory cell 101. FIG. 2B shows an erasing operation of the split gate nonvolatile memory cell 101. FIG. 2C shows a reading operation of the split gate nonvolatile memory cell 101.

Referring to FIG. 2A, in the case where the data writing is carried out in the split gate nonvolatile memory cell 101, the first source/drain diffusion layer 103 serves as a drain and the second source/drain diffusion layer 104 serves as a source. In the data writing, the split gate nonvolatile memory cell 101 sets the first source/drain diffusion layer 103 to be a high potential in comparison with the second source/drain diffusion layer 104. In this manner, hot electrons (electrons in a high energy state) are obtained on a source side of a channel. The data writing is carried out by implanting the hot electrons to the floating gate 105 through the gate oxide film 107. After the writing, the floating gate will be in a negatively-charged state.

Referring to FIG. 2B, in the case where the data of the split gate nonvolatile memory cell 101 is erased, the data erasing is carried out by extracting electrons from the floating gate 105 to the control gate 106 through the tunnel oxide film 108 due to a tunnel current. Specifically, as a mechanism, in the erasing, the electrons are extracted from the floating gate 105 by applying an electric voltage to the control gate 106 to concentrate an electric field to an acute portion (the acute angle portion) of a tip of the floating gate 105. After the erasing, the floating gate will be in a positively-charged state.

Referring to FIG. 2C, in the case where the data reading is carried out in the split gate nonvolatile memory cell 101, a transistor composed of the control gate 106, the first source/drain diffusion layer 103, and the second source/drain diffusion layer 104 is activated by applying a predetermined voltage to the control gate 106. At this moment, a current flowing between the source and the drain changes in response to the electric charges implanted to the floating gate 105. In this manner, the data reading is carried out.

In the split gate nonvolatile memory cell 101 described in patent literature 1, a technique called a self-aligning technique is applied to the floating gate 105, the control gate 106, the source plug 109, and so on. Due to the application of the self-aligning technique, it is possible, in an integrated circuit manufacturing process of a semiconductor and the like, to use a pattern already formed at a certain step as a mask at a next step and to proceed to a next step without positioning the mask. For example, in manufacturing of a MOS transistor, the technique is equivalent to a technique for implanting impurities to form source and drain regions based on the ion implantation method by employing a gate electrode as the mask.

In the case where the split gate nonvolatile memory cell 101 is manufactured by employing the self-aligning technique, a growing step of a polysilicon film needs to be carried out at least four times in order to form the floating gate 105, the control gate 106, the source plug 109, and a gate polysilicon (not shown) for a logic transistor, for example.

To shape the grown polysilicon film, many shaping steps are required after a spacer oxide film is shaped; for example, the dry etching of a floating gate polysilicon film on a source line side, the CMP (Chemical Mechanical Polishing) of a source line polysilicon film, the dry etching of the source line polysilicon film, the dry etching of a floating gate polysilicon film on a word line side, the dry etching of a logic polysilicon film, and the dry etching of a word polysilicon film.

For example, in the manufacturing of the split gate nonvolatile memory cell 101 described in the patent literature 1, the self-aligning etching is carried out separately twice by using the spacer oxide film as a mask in the case of the floating gate polysilicon; one is for the source line side and the other is for the word line side. After that, the control gate 106 is formed by: removing the floating gate polysilicon film; forming a new word line polysilicon film; and carrying out the self-aligning etching without using the lithography.

I have now discovered the following facts.

Each of a plurality of components configuring the split gate nonvolatile memory cell 101 is formed through an extraordinary large number of steps. To adequately form the components, it is required to adequately carry out each one of the steps. As shown in the patent literature 1, the steps, for example, the growth of the polysilicon and the etching and CMP of the polysilicon are repeatedly carried out to form the split gate nonvolatile memory cell 101. The more the number of repeated steps increases, the more the manufacturing cost may increase and the manufacturing period may be extended.

In addition, the polysilicon is a conductive material. Thus, the polysilicon to be removed has to be removed certainly in the etching step. If the polysilicon to be removed remains, the remaining polysilicon may cause a short circuit. As described above, the steps, for example, the growth of the polysilicon and the etching and CMP of the polysilicon are repeatedly carried out in the conventional manufacturing of the split gate nonvolatile memory cell 101. The more the number of repeated steps increases, the higher a possibility of occurrence of the remaining polysilicon becomes. As described above, the remaining polysilicon caused by the increase of the number of repeated steps may be a cause of deterioration of a yield.

Moreover, in a forming step of the source line polysilicon, the CMP of the polysilicon is carried out. When the CMP is carried out, a minute scuff called a scratch may be generated. When the number of repeated steps increases, a possibility of the generation of scratch becomes high and also a possibility of occurrence of a trouble caused by the scratch becomes high.

It is desired that to provide a technique for reducing the number of steps in manufacturing of the split gate nonvolatile storage device.

### SUMMARY

The present invention seeks to solve one or more of the above problems, or to improve upon those problems at least in part.

In one embodiment, a split gate nonvolatile semiconductor storage device includes: a substrate; a floating gate configured to be formed on the substrate through a gate insulating film; a control gate configured to be formed adjacent to the floating gate through a tunnel insulating film; a first source/drain diffusion layer configured to be formed in a surface region of the substrate on a side of the floating gate; a second source/drain diffusion layer configured to be formed in a surface region of the substrate on a side of the control gate; and a silicide configured to contact the first source/drain diffusion layer.

In another embodiment, a split gate nonvolatile semiconductor storage device, includes: a first split gate nonvolatile memory cell; and a second split gate nonvolatile memory cell, wherein a source/drain diffusion layer is shared by the first split gate nonvolatile memory cell and the second split gate nonvolatile memory cell, and wherein the first split gate nonvolatile memory cell and the second split gate nonvolatile memory cell are symmetrical with respect to the source/drain diffusion layer, and wherein the source/drain diffusion layer directly contact a silicide.

In another embodiment, a method of manufacturing a split gate nonvolatile semiconductor storage device, includes: forming a semiconductor structure, the semiconductor structure including: a gate insulator formation film formed on a substrate; a floating gate polysilicon film formed on the gate insulator formation film, and having a concave portion with a first slant portion at one end and a second slant portion at the other end; a spacer formation insulating film formed on the floating gate polysilicon film, and having an opening portion with a first side surface extending upward from an end of the first slant portion and a second side surface extending upward from an end of the second slant portion, the opening portion corresponding to the concave portion; a first spacer insulating film covering the first slant portion and the first side surface, and a second spacer insulating film covering the second slant portion and the second the surface; removing the spacer formation insulating film without removing the first spacer insulating film and the second spacer insulating film to expose partially a surface of the floating gate polysilicon film; removing selectively the floating gate polysilicon film and the gate insulator formation film using the first spacer insulating film and the second spacer insulating film as masks to forma floating gate with an acute portion and a gate insulating film while exposing partially the substrate; forming a tunnel insulating film covering an exposed surface of the substrate, a side wall of the gate insulating film, and a side wall of the floating gate; removing the tunnel insulating film between the first spacer insulating film and the second spacer insulating film to expose a surface of the substrate; and forming a silicide between the first spacer insulating film and the second spacer insulating film.

In another embodiment, a method of manufacturing a split gate nonvolatile semiconductor storage device, includes: forming a first split gate nonvolatile memory cell and a second split gate nonvolatile memory cell, wherein a source/drain diffusion layer is shared by the first split gate nonvolatile memory cell and the second split gate nonvolatile memory cell, and wherein the first split gate nonvolatile memory cell and the second split gate nonvolatile memory cell are symmetrical with respect to the source/drain diffusion layer; and forming a silicide so as to contact the source/drain diffusion layer.

According to the present invention, the number of steps in manufacturing of the split gate nonvolatile storage device can be reduced.

In addition, when the number of steps in manufacturing of the split gate nonvolatile storage device is reduced, generation of remaining polysilicon that causes deterioration of a yield also can be suppressed.

Moreover, occurrence of a trouble caused by the scratch can be suppressed by reducing the number of times of the CMP of polysilicon.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view showing a configuration of a related-art split gate nonvolatile memory;

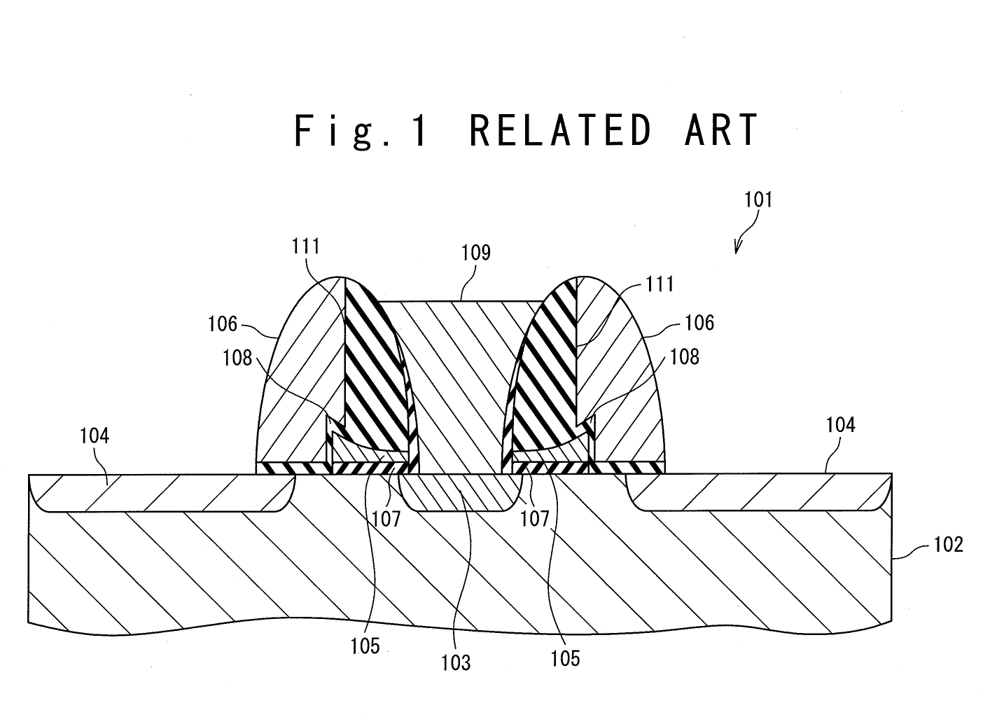

FIGS. 2A to 2C are schematic diagrams showing operations of the related-art split gate nonvolatile memory cell;

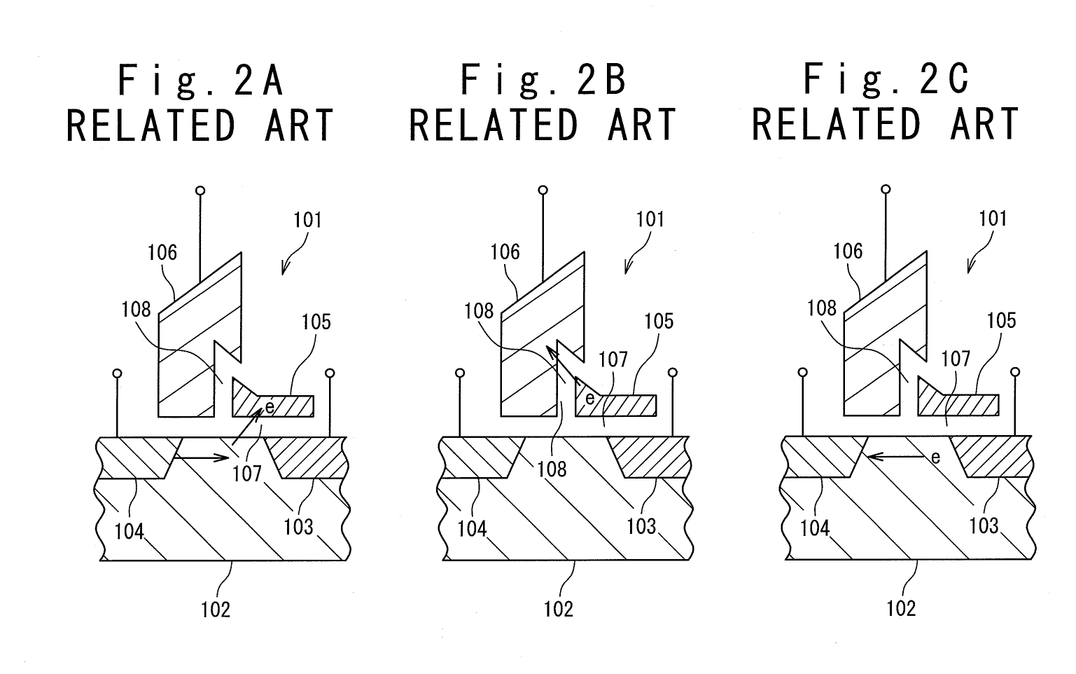

FIG. 3 is a cross-sectional view exemplifying a configuration of a split gate nonvolatile memory cell according to a first embodiment;

FIG. 4 is a plane view exemplifying the configuration of the split gate nonvolatile memory cell according to the first embodiment;

FIG. 5 is a cross-sectional view exemplifying a configuration of a semiconductor structure of a first step in manufacturing of the split gate nonvolatile memory cell according to the first embodiment;

FIG. 6 is a plane view exemplifying the configuration of the semiconductor structure of the first step in the manufacturing of the split gate nonvolatile memory cell according to the first embodiment;

FIG. 7 is a cross-sectional view exemplifying a configuration of a semiconductor structure of a second step in the manufacturing of the split gate nonvolatile memory cell according to the first embodiment;

FIG. 8 is a cross-sectional view exemplifying a configuration of a semiconductor structure of a third step in the manufacturing of the split gate nonvolatile memory cell according to the first embodiment;

FIG. 9 is a cross-sectional view exemplifying a configuration of a semiconductor structure of a fourth step in the manufacturing of the split gate nonvolatile memory cell according to the first embodiment;

FIG. 10 is a cross-sectional view exemplifying a configuration of a semiconductor structure of a fifth step in the manufacturing of the split gate nonvolatile memory cell according to the first embodiment;

FIG. 11 is a cross-sectional view exemplifying a configuration of a semiconductor structure of a sixth step in the manufacturing of the split gate nonvolatile memory cell according to the first embodiment;

FIG. 12 is a cross-sectional view exemplifying a configuration of a semiconductor structure of a seventh step in the manufacturing of the split gate nonvolatile memory cell according to the first embodiment;

FIG. 13 is a cross-sectional view exemplifying a configuration of a semiconductor structure of an eighth step in the manufacturing of the split gate nonvolatile memory cell according to the first embodiment;

FIG. 14 is a cross-sectional view exemplifying a configuration of a semiconductor structure of a ninth step in the manufacturing of the split gate nonvolatile memory cell according to the first embodiment;

FIG. 15 is a cross-sectional view exemplifying a configuration of a semiconductor structure of a tenth step in the manufacturing of the split gate nonvolatile memory cell according to the first embodiment;

FIG. 16 is a cross-sectional view exemplifying a configuration of a semiconductor structure of an eleventh step in the manufacturing of the split gate nonvolatile memory cell according to the first embodiment;

FIG. 17 is a cross-sectional view exemplifying a configuration of a semiconductor structure of a twelfth step in the manufacturing of the split gate nonvolatile memory cell according to the first embodiment;

FIG. 18 is a cross-sectional view exemplifying a configuration of a semiconductor structure of a thirteenth step in the manufacturing of the split gate nonvolatile memory cell according to the first embodiment;

FIG. 19 is a cross-sectional view exemplifying a configuration of a semiconductor structure of a fourteenth step in the manufacturing of the split gate nonvolatile memory cell according to the first embodiment;

FIG. 20 is a cross-sectional view exemplifying a configuration of a semiconductor structure of a fifteenth step in the manufacturing of the split gate nonvolatile memory cell according to the first embodiment;

FIG. 21 is a cross-sectional view exemplifying a configuration of the split gate nonvolatile memory cell according to a second embodiment;

FIG. 22 is a plane view exemplifying configurations of a well and an element isolating region in the split gate nonvolatile memory cell according to the second embodiment;

FIG. 23 is a cross-sectional view exemplifying a configuration of a semiconductor structure of a seventh step in manufacturing of the split gate nonvolatile memory cell according to the second embodiment;

FIG. 24 is a cross-sectional view exemplifying a configuration of a semiconductor structure of an eighth step in the manufacturing of the split gate nonvolatile memory cell according to the second embodiment;

FIG. 25 is a cross-sectional view exemplifying a configuration of a semiconductor structure of a ninth step in the manufacturing of the split gate nonvolatile memory cell according to the second embodiment;

FIG. 26 is a cross-sectional view exemplifying a configuration of a semiconductor structure of a tenth step in the manufacturing of the split gate nonvolatile memory cell according to the second embodiment;

FIG. 27 is a cross-sectional view exemplifying a configuration of a semiconductor structure of an eleventh step in the manufacturing of the split gate nonvolatile memory cell according to the second embodiment;

FIG. 28 is a cross-sectional view exemplifying a configuration of a semiconductor structure of a twelfth step in the manufacturing of the split gate nonvolatile memory cell according to the second embodiment;

FIG. 29 is a cross-sectional view exemplifying a configuration of a semiconductor structure of a thirteenth step in the manufacturing of the split gate nonvolatile memory cell according to the second embodiment; and

FIG. 30 is a cross-sectional view exemplifying a configuration of a semiconductor structure of a fourteenth step in the manufacturing of the split gate nonvolatile memory cell according to the second embodiment.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

An embodiment of the present invention will be described below with reference to drawings. In the drawings used for describing the present embodiment, the same numeral basically represents the same member, and thereby omitting repeated explanation of the member.

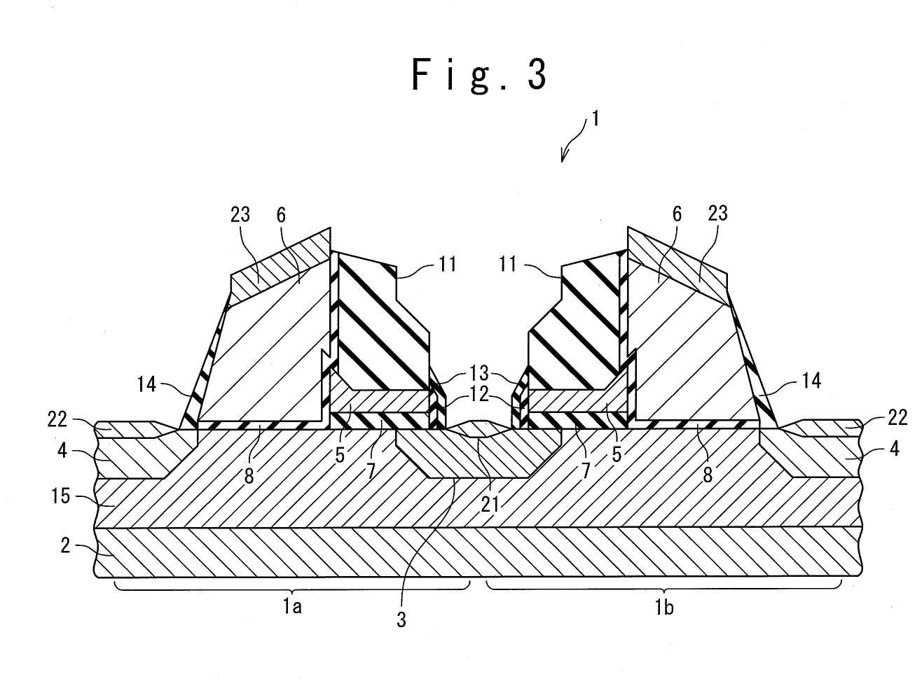

FIG. 3 is a cross-sectional view exemplifying a configuration of a split gate nonvolatile memory cell according to the present embodiment. The split gate nonvolatile memory cell 1 includes a first cell 1a and a second cell 1b. Each of the first cell 1a and the second cell 1b holds one-bit information. In addition, the split gate nonvolatile memory cell 1 includes a first source/drain diffusion layer 3 and a second source/drain diffusion layer 4. The first source/drain diffusion layer 3 and the second source/drain diffusion layer 4 are formed in a surface region of a well 15 of a substrate 2.

As exemplified in FIG. 3, the split gate nonvolatile memory cell 1 includes a floating gate 5 and a control gate 6. The floating gate 5 is provided on the substrate 2 through the gate insulating film 7. In addition, the control gate 6 is provided on the substrate 2 through a tunnel insulating film 8. Moreover, the tunnel insulating film 8 is provided between the floating gate 5 and the control gate 6. The floating gate 5 is provided with an acute angle portion. Additionally, a spacer insulating film 11 is provided on the floating gate 5. A side wall insulating film 12 and a side wall insulating film 13 are provided on a side opposite to the acute angle portion of the floating gate 5. The floating gate 5 is electrically insulated from surrounding conductive members due to actions of the gate insulating film 7, the tunnel insulating film 8, the spacer insulating film 11, the side wall insulating film 12, and the side wall insulating film 13.

The tunnel insulating film 8 is provided continuously from an intermediate portion between the floating gate 5 and the control gate 6 to an intermediate portion between the control gate 6 and the well 15. A side wall insulating film 14 is provided on an out side of the control gate 6 (on a side surface opposite to a side surface on the floating gate 5 side). A control gate silicide 23 is formed on the control gate 6.

In the split gate nonvolatile memory cell 1 according to the present embodiment, a second source/drain side silicide 22 is formed on the second source/drain diffusion layer 4 so as to contact to the second source/drain diffusion layer 4. A first source/drain side silicide 21 is formed on the first source/drain diffusion layer 3 so as to contact to the first source/drain diffusion layer 3. The split gate nonvolatile memory cell 1 according to the present embodiment is not provided with the conductive material such as the polysilicon between the first source/drain diffusion layer 3 and the first source/drain side silicide 21. Accordingly, almost all of steps employed to form the conductive material can be omitted. The reduction of the number of steps related to the manufacturing of the split gate nonvolatile memory cell 1 can suppress the deterioration of a yield related to the manufacturing of the split gate nonvolatile memory cell 1. In addition, since the conductive material is not arranged on the split gate nonvolatile memory cell 1 according to the present embodiment, the split gate nonvolatile memory cell 1 can be formed without considering a resistance of the conductive material.

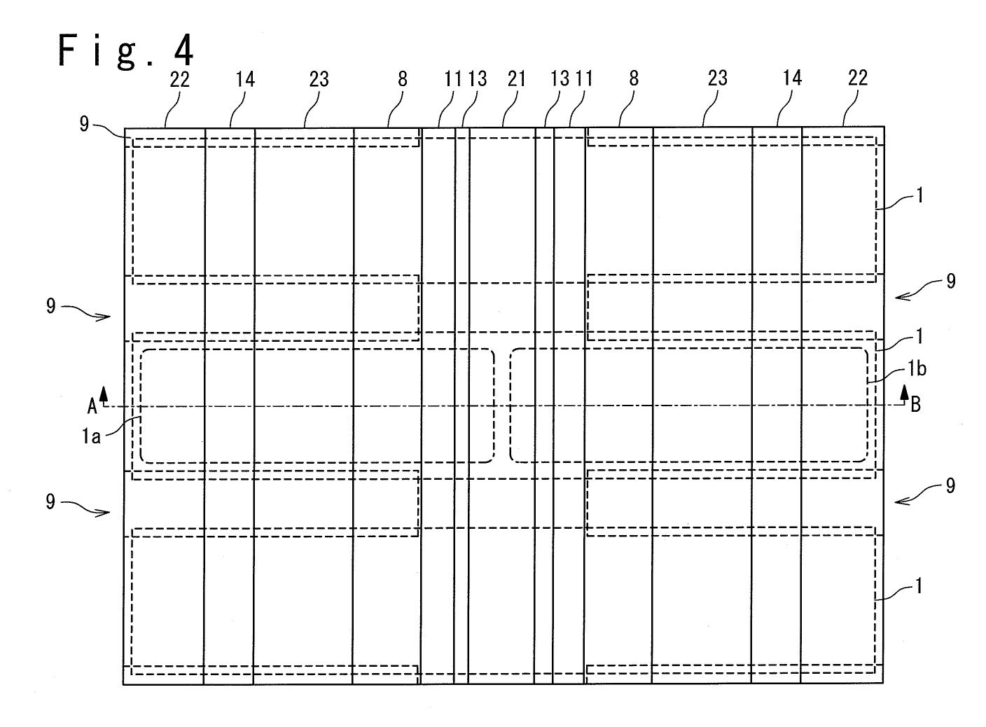

FIG. 4 is a plane view exemplifying a configuration of the split gate nonvolatile memory cell 1 according to the present embodiment. The above-mentioned cross-sectional view exemplifies a cross section taken along a dashed line from a position A to a position B shown in the plane view. As shown in FIG. 4, a storage device having the split gate nonvolatile memory cell 1 according to the present embodiment includes a plurality of the split gate nonvolatile memory cells 1 arranged in an array. The plurality of split gate nonvolatile memory cells 1 is isolated by the element isolation regions 9 (e.g. shallow trench insulators (STI)) in a direction perpendicular to the dashed line from the position A to the position B. That is, the second source/drain diffusion layer 4 is isolated from the second source/drain diffusion layer 4 provided in an adjacent split gate nonvolatile memory cell 1 by the element isolation regions 9. In addition, the first source/drain side silicide 21, the second source/drain side silicide 22, and the control gate silicide 23 are formed so as to extend in a direction approximately vertical to a direction where the element isolation regions 9 extend. Meanwhile, the element isolation regions 9 are formed so as not to isolate the well 15 and the substrate 2 under the first source/drain side silicide 21, which will be described in detail below.

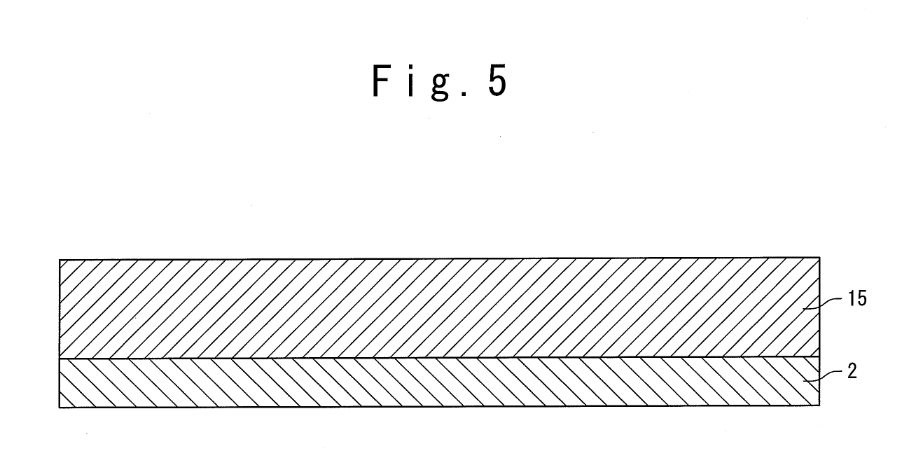

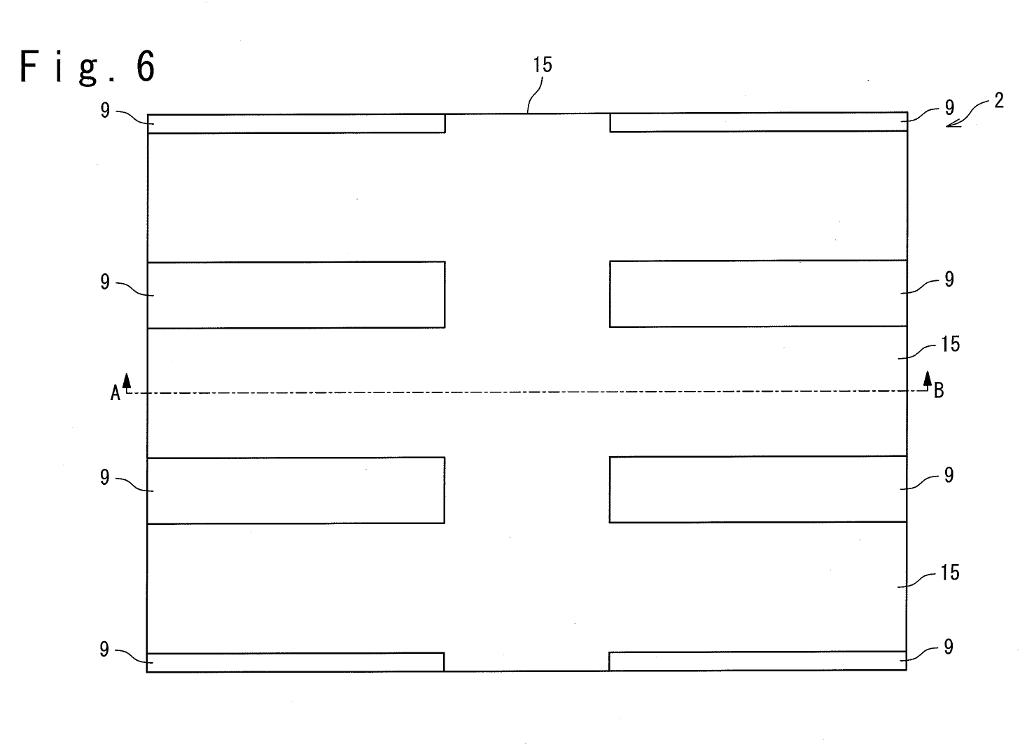

A method of manufacturing the split gate nonvolatile memory cell 1 according to the present embodiment will be explained below. FIG. 5 is a cross-sectional view exemplifying a configuration of a semiconductor structure of a first step to manufacture the split gate nonvolatile memory cell 1 according to the present embodiment. In the first step, the well 15 is formed in a surface region of the substrate 2. FIG. 6 is a plane view exemplifying the configuration of the semiconductor structure of the first step to manufacture the split gate nonvolatile memory cell 1 according to the present embodiment. As shown in FIG. 6, after the well 15 is formed in the substrate 2 in the first step, the element isolation regions 9 for isolating respective portions of the well 15 are formed. The element isolation regions 9 are formed so as not to isolate a portion where the first source/drain side silicide 21 is formed in a subsequent step. In other words, in the split gate nonvolatile memory cell 1 according to the first embodiment, the element isolation regions 9 are configured without isolating portions between the first source/drain diffusion layers 3 of adjacent memory cells.

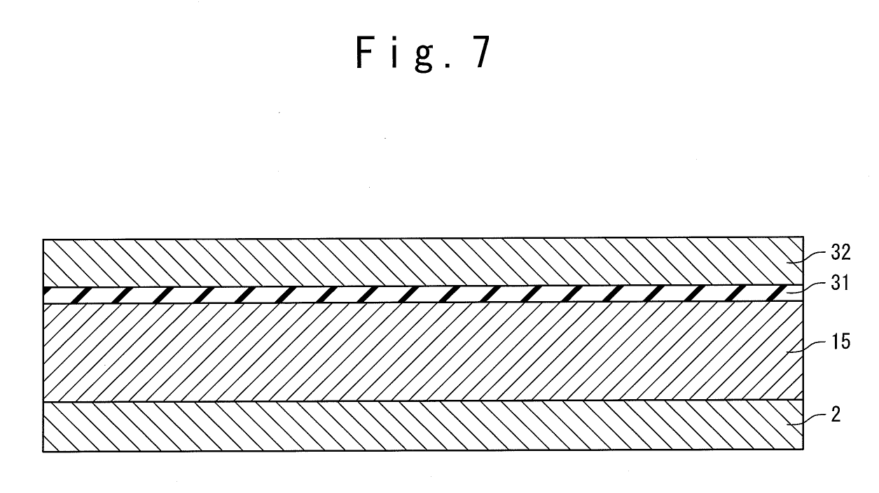

FIG. 7 is a cross-sectional view exemplifying a configuration of a semiconductor structure of a second step to manufacture the split gate nonvolatile memory cell 1 according to the present embodiment. In the second step, a gate insulating film oxide film 31 is formed on the well 15. The gate insulating film oxide film 31 becomes the gate insulating film 7 of the split gate nonvolatile memory cell 1 through subsequent steps. In addition, in the second step, a floating gate polysilicon film 32 is formed on the gate insulating film oxide film 31. The floating gate polysilicon film 32 becomes the floating gate 5 of the split gate nonvolatile memory cell 1 through subsequent steps.

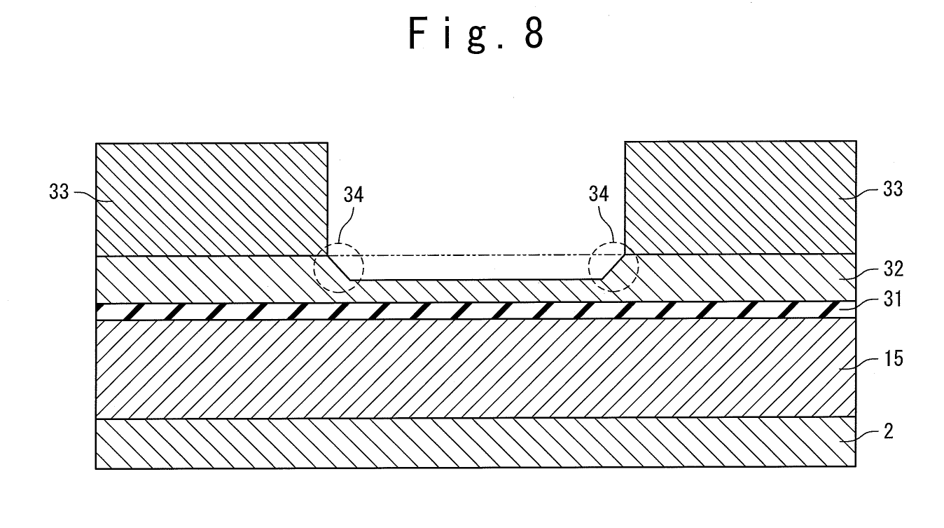

FIG. 8 is a cross-sectional view exemplifying a configuration of a semiconductor structure of a third step to manufacture the split gate nonvolatile memory cell 1 according to the present embodiment. In the third step, a first nitride film 33 having an opening portion is formed on the floating gate polysilicon film 32. Then, for the exposed floating gate polysilicon film 32, slant portions 34 each becoming a projecting portion of the floating gate 5 through subsequent steps are formed in portions contacting to side surfaces of the opening portion.

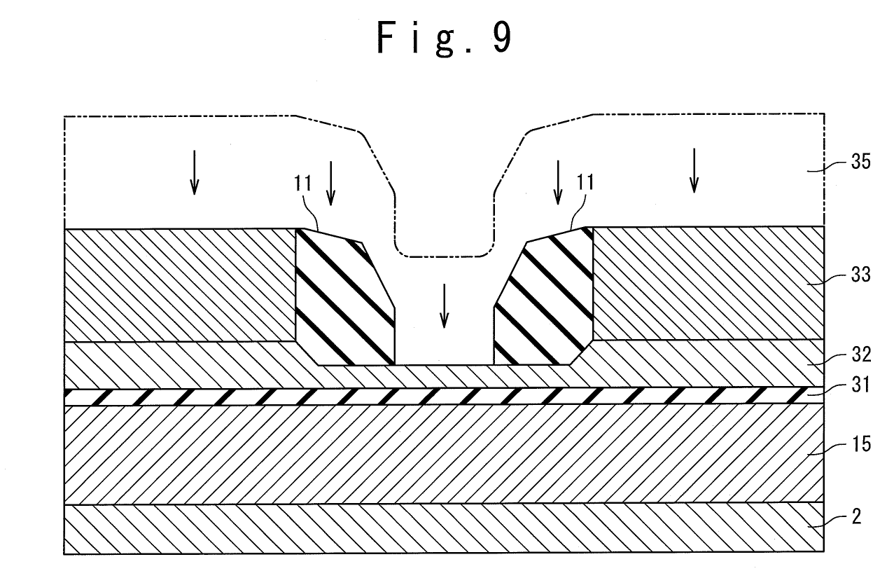

FIG. 9 is a cross-sectional view exemplifying a configuration of a semiconductor structure of a fourth step to manufacture the split gate nonvolatile memory cell 1 according to the present embodiment. In the fourth step, a spacer insulating film oxide film 35 is formed to embed the above-mentioned opening portion. Then, the spacer insulating films 11 with the sidewall shape are formed on side surfaces of the nitride film 33 by etching back the spacer insulating film oxide film 35.

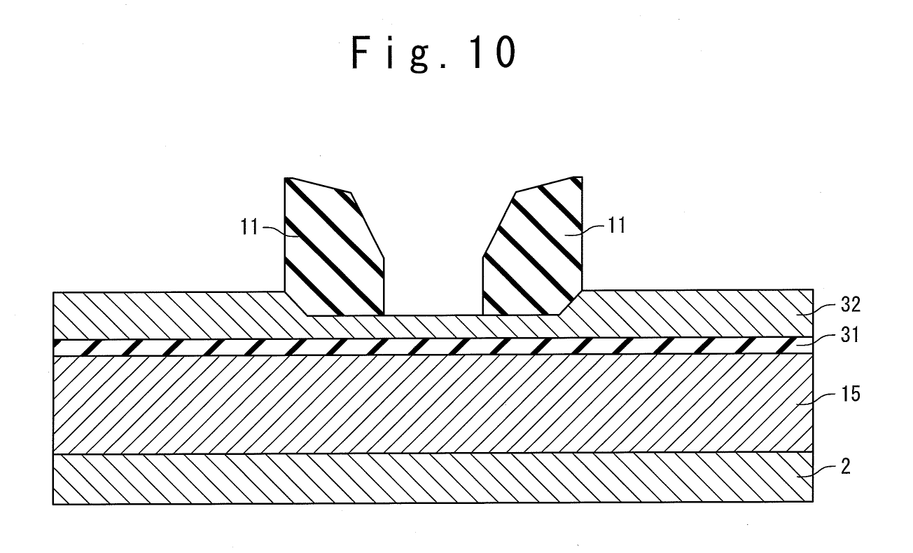

FIG. 10 is a cross-sectional view exemplifying a configuration of a semiconductor structure of a fifth step to manufacture the split gate nonvolatile memory cell 1 according to the present embodiment. In the fifth step, the first nitride film 33 covering the floating gate polysilicon film 32 is removed. Thus, a surface of the floating gate polysilicon film 32 covered until then is exposed.

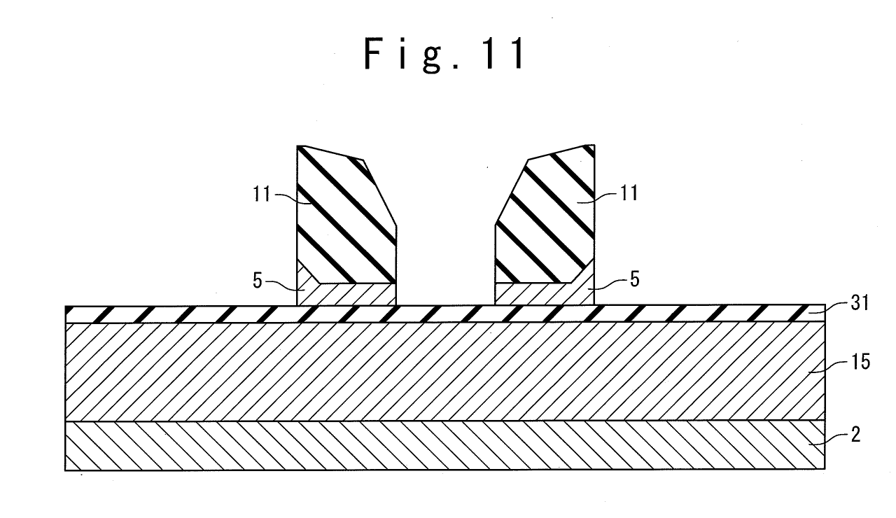

FIG. 11 is a cross-sectional view exemplifying a configuration of a semiconductor structure of a sixth step to manufacture the split gate nonvolatile memory cell 1 according to the present embodiment. In the sixth step, the floating gates 5 are formed by selectively etching an exposed portion of the floating gate polysilicon film 32. The floating gates 5 are formed by selectively etching the floating gate polysilicon film 32 with the spacer insulating films 11 acted as masks. The etching is carried out by using the self-aligning technique. In addition, in the sixth step, the gate insulating film oxide film 31 under the floating gate polysilicon film 32 is exposed.

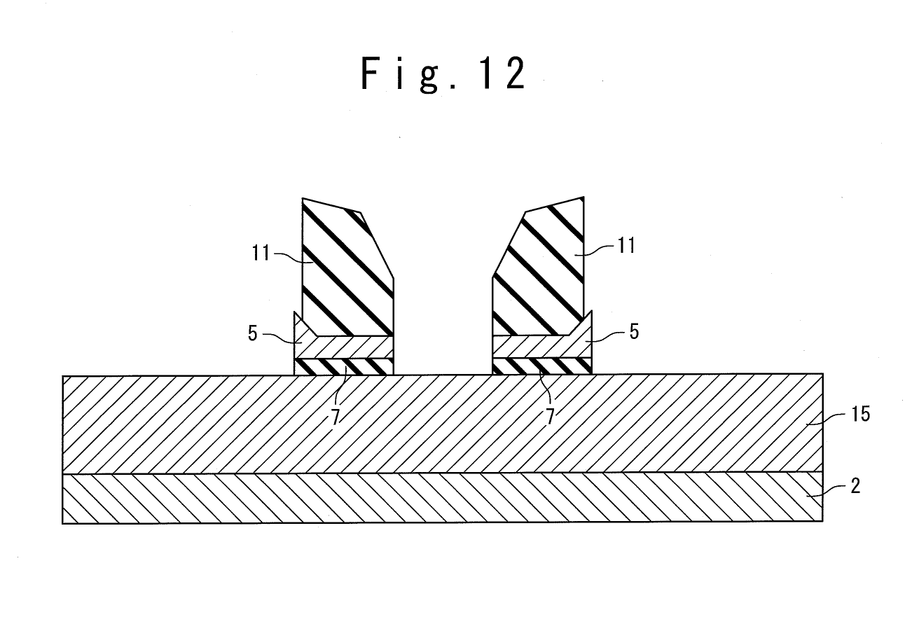

FIG. 12 is a cross-sectional view exemplifying a configuration of a semiconductor structure of a seventh step to manufacture the split gate nonvolatile memory cell 1 according to the present embodiment. In the seventh step, the gate insulating film oxide film 31 is selectively etched by acting the spacer insulating films 11 and the floating gates 5 under the spacer insulating films 11 as masks. The gate insulating films 7 between the floating gates 5 and the wells 15 are formed by the etching. At this time, the acute angle portion appears at an edge of the control gate side in the floating gate 5.

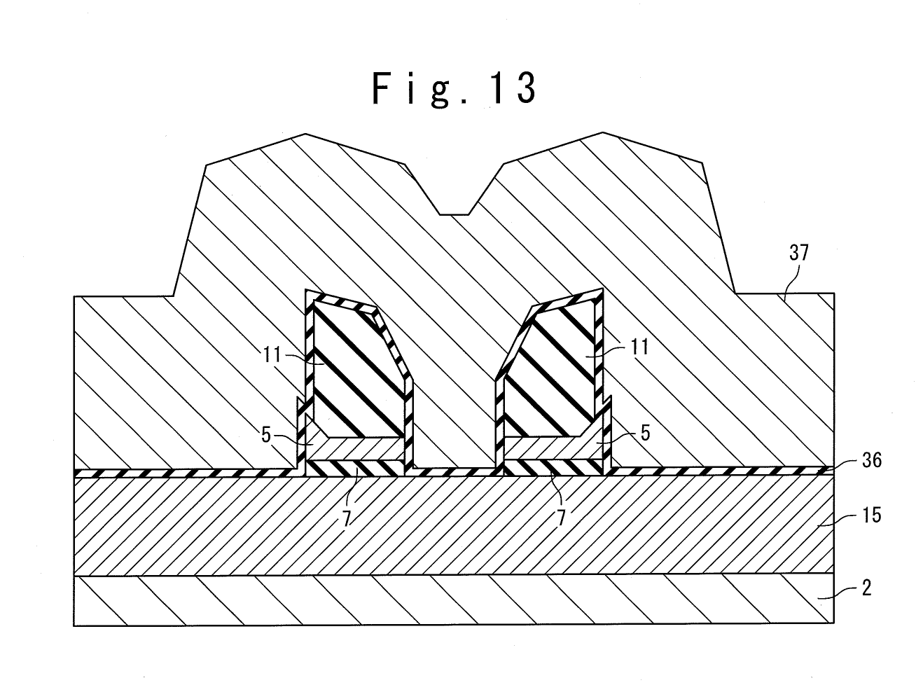

FIG. 13 is a cross-sectional view exemplifying a configuration of a semiconductor structure of an eighth step to manufacture the split gate nonvolatile memory cell 1 according to the present embodiment. In the eighth step, a tunnel insulating film oxide film 36 entirely covering the semiconductor structure is formed. The tunnel insulating film oxide film 36 becomes the tunnel insulating film 8 through subsequent steps. Then, a control gate polysilicon film 37 is formed on the tunnel insulating film oxide film 36. The control gate polysilicon film 37 is formed to have a sufficient film thickness required to form the control gate 6 in subsequent steps. On this occasion, the opening portion between the spacer insulating films 11 is filled with the control gate polysilicon film 37.

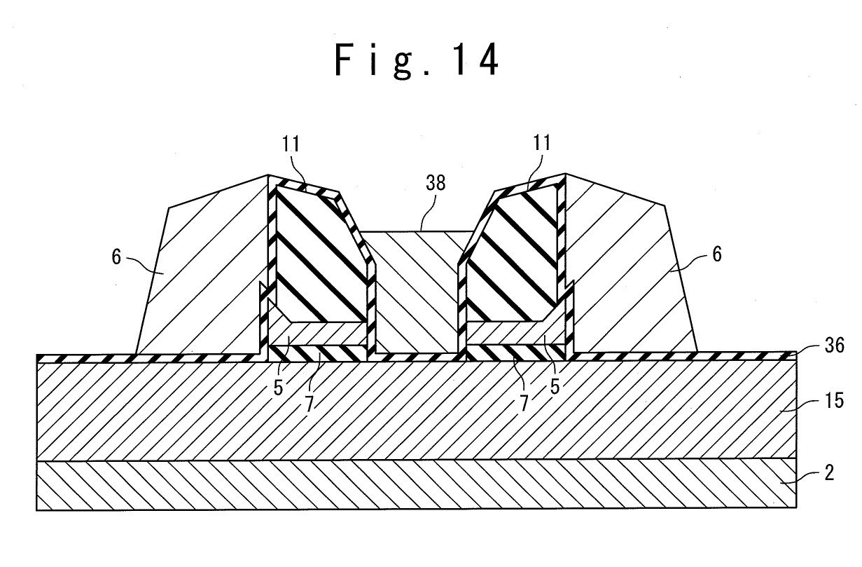

FIG. 14 is a cross-sectional view exemplifying a configuration of a semiconductor structure of a ninth step to manufacture the split gate nonvolatile memory cell 1 according to the present embodiment. In the ninth step, the control gate 6 is formed by etching back the above-mentioned control gate polysilicon film 37. On this occasion, the tunnel insulating film oxide film 36 covered with the control gate polysilicon film 37 is partially exposed. In the ninth step, a remaining polysilicon 38 as a residue of the control gate polysilicon film 37 remains at an opening portion between the spacer insulating films 11. Meanwhile, in the present embodiment, the remaining polysilicon 38 does not need to be remained.

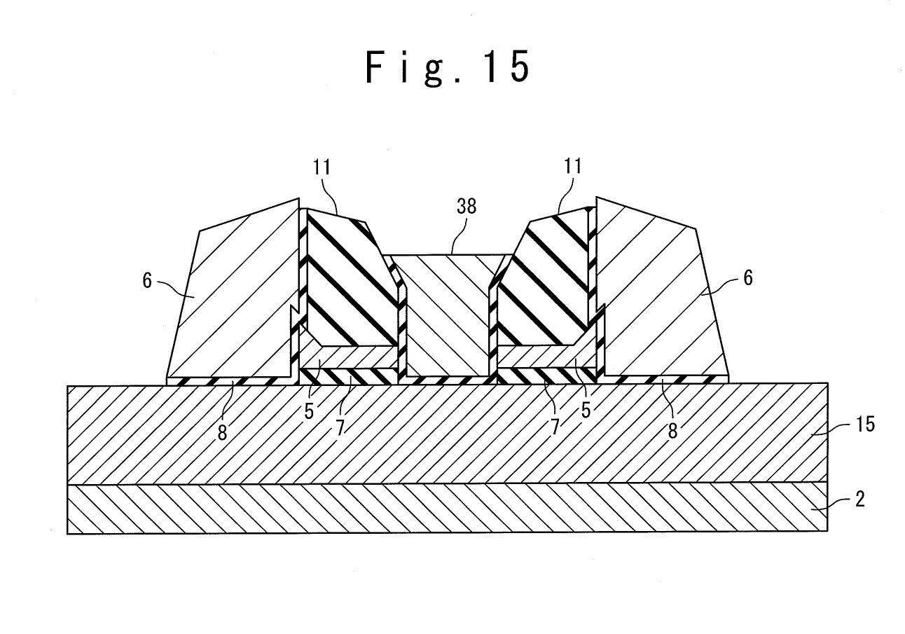

FIG. 15 is a cross-sectional view exemplifying a configuration of a semiconductor structure of a tenth step to manufacture the split gate nonvolatile memory cell 1 according to the present embodiment. In the tenth step, the exposed tunnel insulating film oxide film 36 is removed with the control gates 6 and the remaining polysilicon 38 acting as masks. In the tenth step, the tunnel insulating films 8 are formed by removing the tunnel insulating oxide film 36 on the spacer insulating films 11 and the tunnel insulating film oxide film 36 on the well 15.

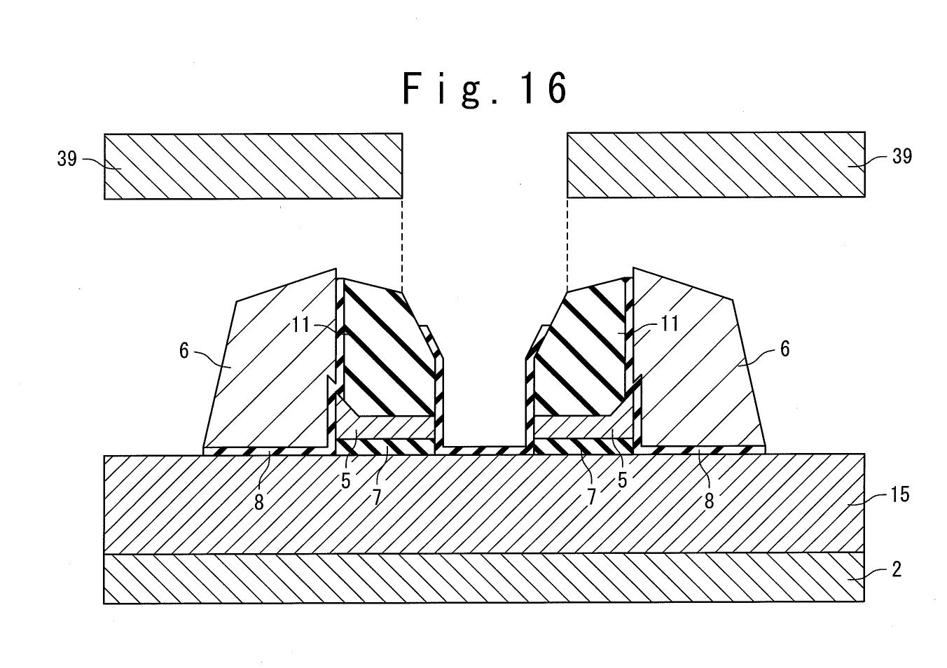

FIG. 16 is a cross-sectional view exemplifying a configuration of the semiconductor structure of an eleventh step to manufacture the split gate nonvolatile memory cell 1 according to the present embodiment. In the eleventh step, the remaining polysilicon 38 is removed by using a photoresist 39 having an opening portion at a position corresponding to an opening portion between the spacer insulating films 11. In the eleventh step, the resist that has an opening portion at a position corresponding to the first source/drain side silicide 21 of the split gate nonvolatile memory cell 1 may be arranged in a photolithography step using the photoresist 39. In that case, since the remaining polysilicon 38 is not covered with the resist, the remaining polysilicon 38 is removed by the etching.

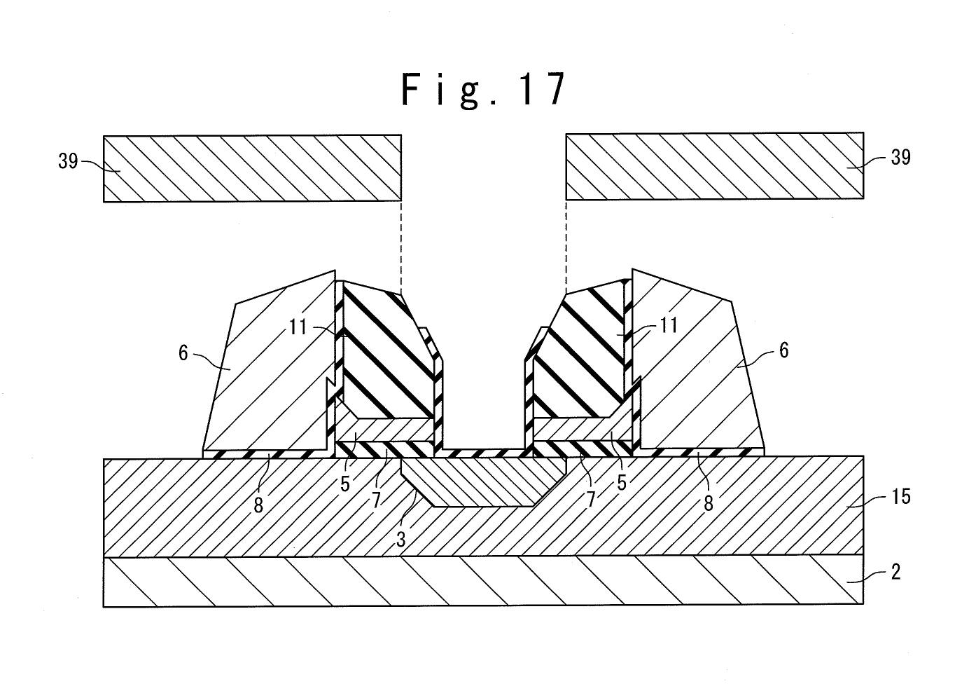

FIG. 17 is a cross-sectional view exemplifying a configuration of a semiconductor structure of a twelfth step to manufacture the split gate nonvolatile memory cell 1 according to the present embodiment. In the twelfth step, impurities (dopants) are implanted into the well 15 to form the first source/drain diffusion layer 3.

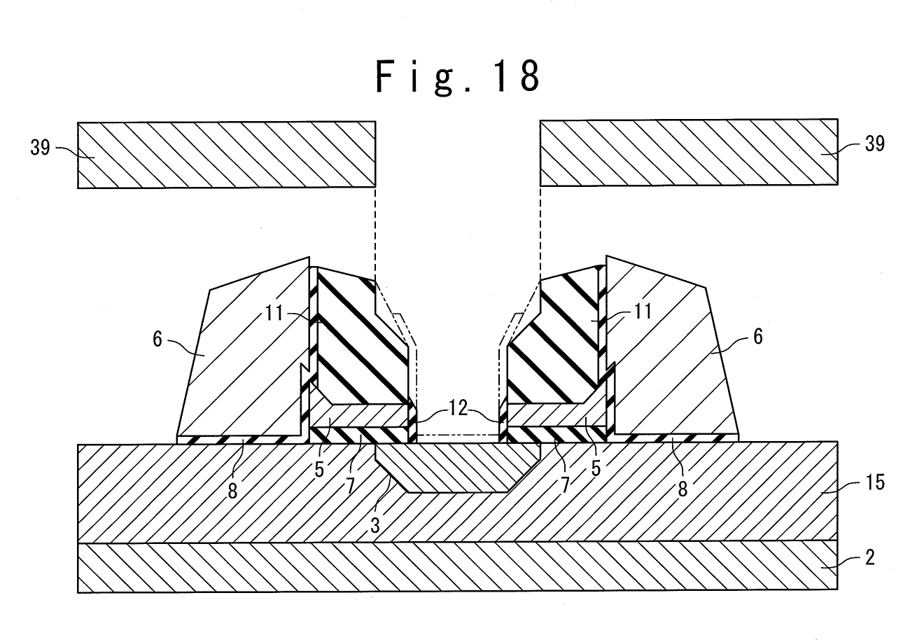

FIG. 18 is a cross-sectional view exemplifying a configuration of a semiconductor structure of a thirteenth step to manufacture the split gate nonvolatile memory cell 1 according to the present embodiment. In the thirteenth step, the tunnel insulating film oxide film 36 formed at a position corresponding to the first source/drain side silicide 21 of the split gate nonvolatile memory cell 1 is selectively removed by using the photoresist 39, and thereby forming the side wall insulating films 12. Meanwhile, this step may employ the above-mentioned resist. In the thirteenth step, the side wall insulating films 12 are formed so as to cover the side surfaces of the floating gates 5.

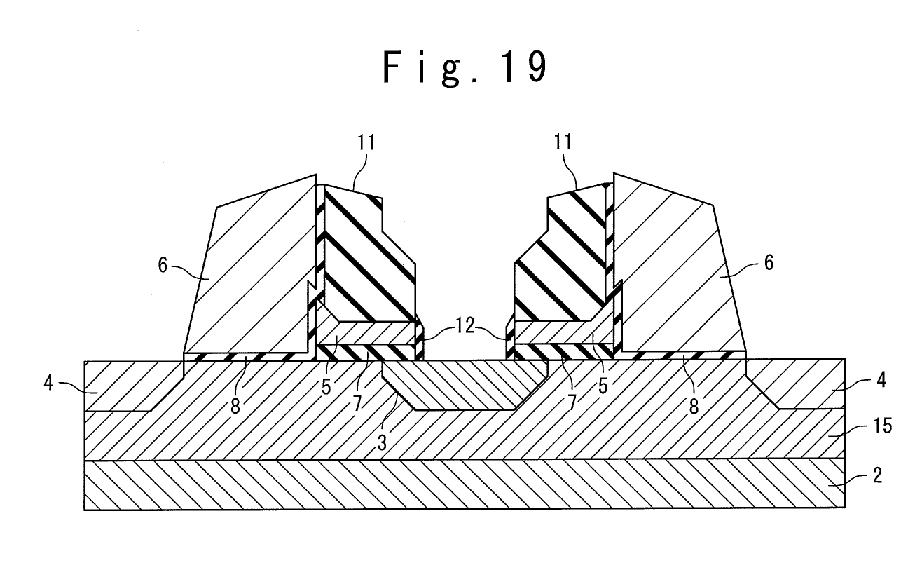

FIG. 19 is a cross-sectional view exemplifying a configuration of a semiconductor structure of a fourteenth step to manufacture the split gate nonvolatile memory cell 1 according to the present embodiment. In the fourteenth step, impurities (dopants) are implanted into the well 15 to form the second source/drain diffusion layers 4.

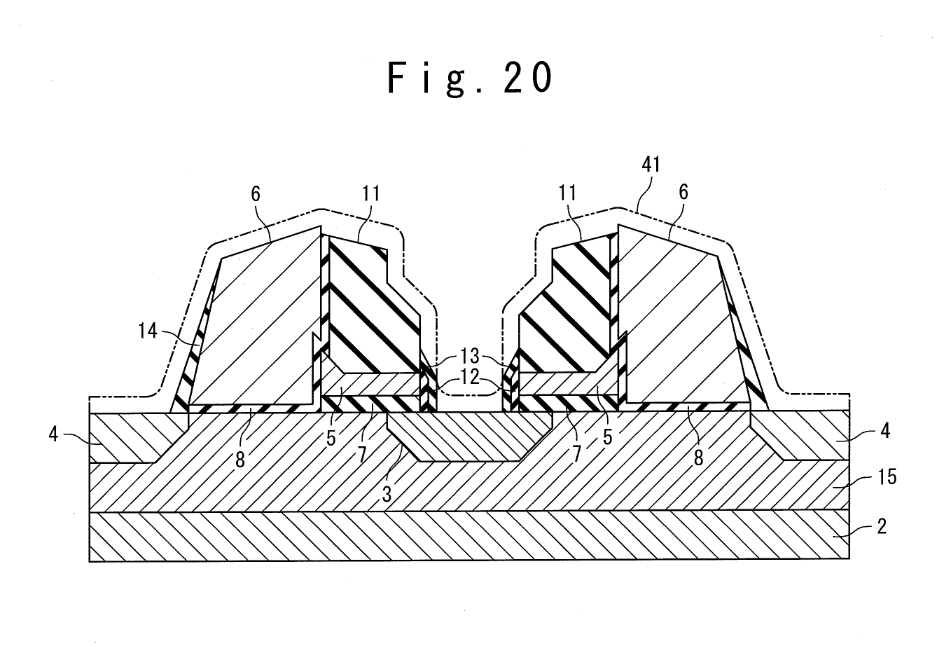

FIG. 20 is a cross-sectional view exemplifying a configuration of a semiconductor structure of a fifteenth step to manufacture the split gate nonvolatile memory cell 1 according to the present embodiment. In the fifteenth step, after the side wall oxide film 41 entirely covering the semiconductor structure has been formed, the side wall insulating films 13 and the side wall insulating films 14 are formed by etching back the side wall oxide film 41.

After that, the first source/drain side silicide 21, the second source/drain side silicides 22, and the control gate silicides 23 are formed as exemplified in the above-described FIG. 3, and thereby the split gate nonvolatile memory cell 1 according to the present embodiment is configured.

### Second Embodiment

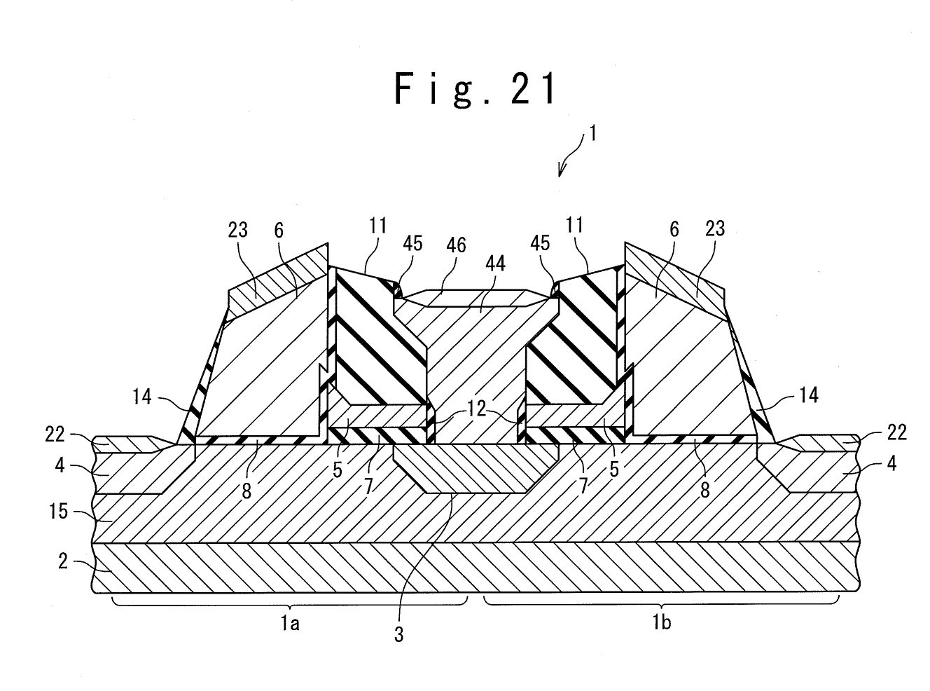

A second embodiment of the present invention will be explained below. FIG. 21 is a cross-sectional view exemplifying a configuration of the split gate nonvolatile memory cell 1 according to a second embodiment. The split gate nonvolatile memory cell 1 according to the second embodiment includes a source plug 44 on the first source/drain diffusion layer 3 and a silicide 46 on the source plug 44. In the split gate nonvolatile memory cell 1 according to the second embodiment, the source plug 44 is formed in the same step as that to form the control gate 6.

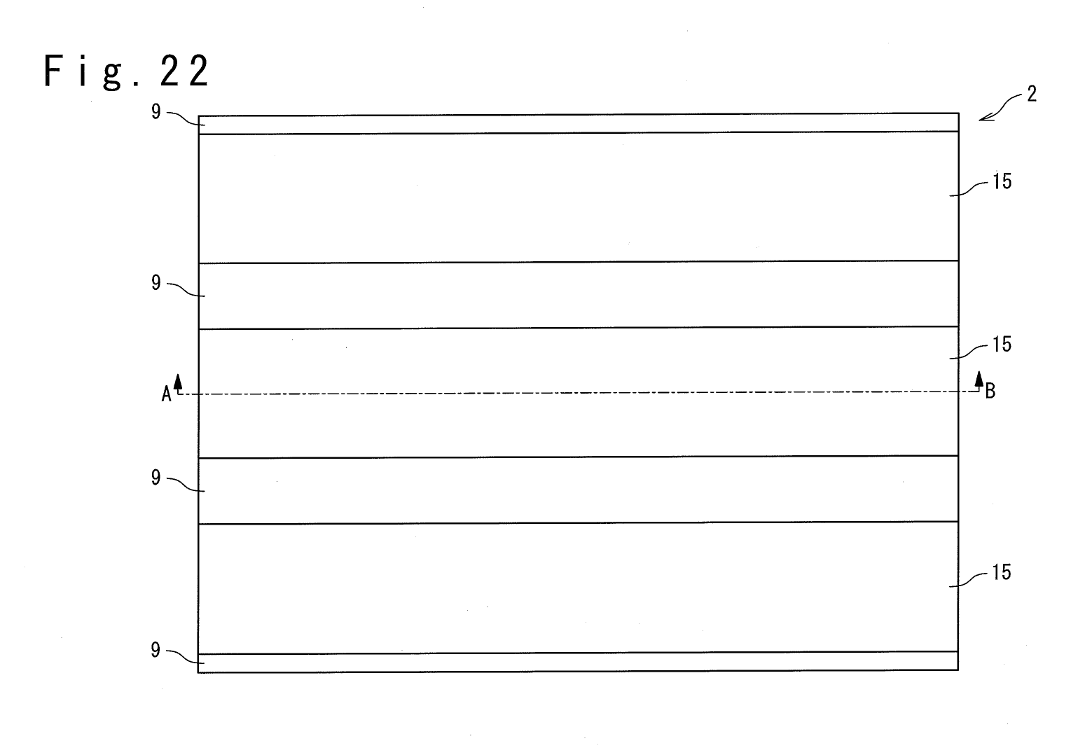

FIG. 22 is a plane view exemplifying a configuration of the well 15 and the element isolation region 9 in the split gate nonvolatile memory cell 1 according to the second embodiment. After the well 15 is formed on the substrate 2, the element isolation regions 9 (e.g. shallow trench insulators (STI)) are formed so as to isolate portions of the well 15 in a direction perpendicular to the dashed line from the position A to the position B. That is, the second source/drain diffusion layer 4 is isolated from the second source/drain diffusion layer 4 provided in an adjacent split gate nonvolatile memory cell 1 by the element isolation regions 9. In addition, the first source/drain diffusion layer 3 is isolated from the first source/drain diffusion layer 3 provided in the adjacent split gate nonvolatile memory cell 1 by the element isolation regions 9. In the split gate nonvolatile memory cell 1 according to the second embodiment, the source plugs 44 of the adjacent memory cells are connected each other. Accordingly, the element isolation regions 9 according to the second embodiment are different from the element isolation regions 9 according to the first embodiment, and isolate the portions of the well 15 at the first source/drain diffusion layers 3 of the adjacent memory cells.

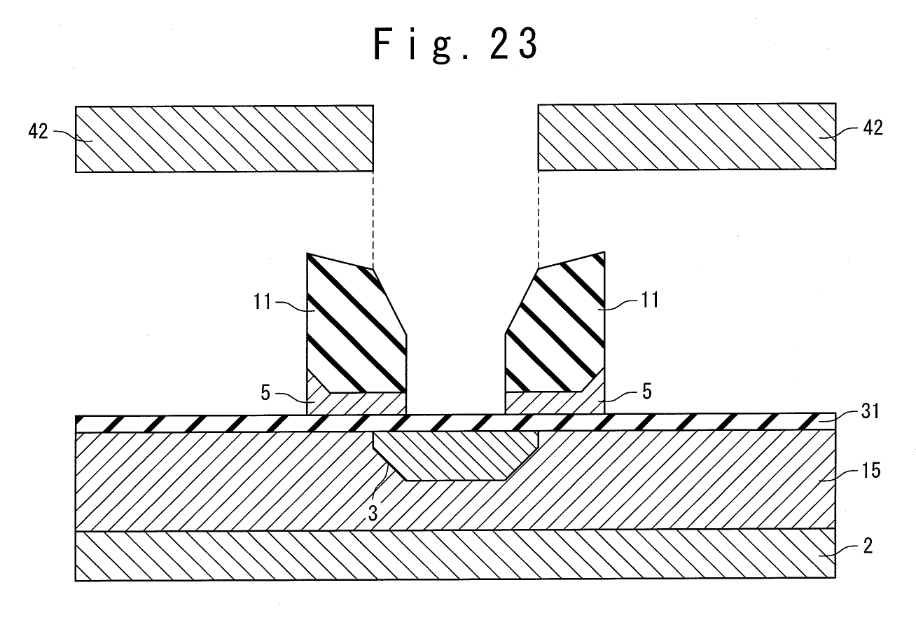

The manufacturing of the split gate nonvolatile memory cell 1 according to the second embodiment will be explained below. In the manufacturing according to the second embodiment, the first to sixth steps are the same as those according to the above-described first embodiment. Accordingly, the explanations from the first to sixth steps will be omitted. FIG. 23 is a cross-sectional view exemplifying a configuration of a semiconductor structure of a seventh step to manufacture the split gate nonvolatile memory cell 1 according to the second embodiment. In the seventh step, after the floating gate 5 has been formed, the photoresist 42 is formed before the gate insulating film oxide film 31 is selectively removed. The photoresist 42 has an opening portion at a position corresponding to an opening portion between the spacer insulating films 11 in the same manner as that of the photo resist 39 according to the first embodiment. The first source/drain diffusion layer 3 is formed in a surface region of the well 15 by using the ion implantation with the photo resist 42 as a mask. In the seventh step, the resist that hays an opening portion at a position corresponding to the first source/drain side suicide 21 of the split gate nonvolatile memory cell 1 may be arranged in a photolithography step using the photoresist 42.

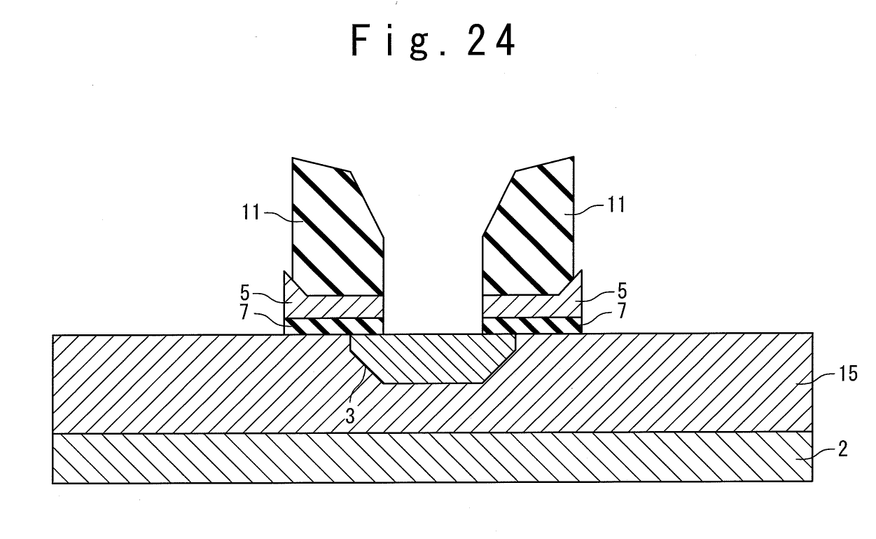

FIG. 24 is a cross-sectional view exemplifying a configuration of a semiconductor structure of an eighth step to manufacture the split gate nonvolatile memory cell 1 according to the second embodiment. In the eighth step, the exposed gate insulating film oxide film 31 is removed by the etching after the photoresist 42 (or a resist) has been removed. In this step, the gate insulating films 7 lying under the floating gates 5 are formed. At this time, the acute angle portion appears at an edge of the control gate side in the floating gate 5.

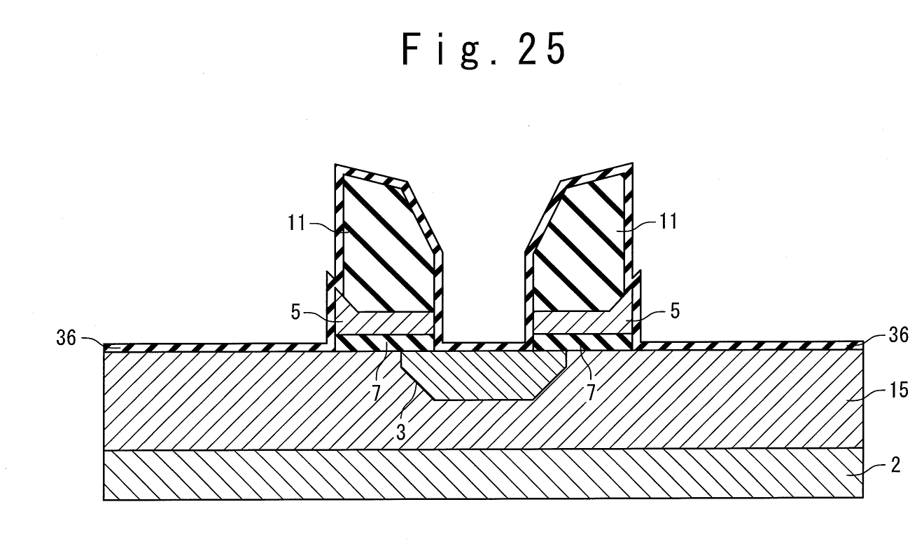

FIG. 25 is a cross-sectional view exemplifying a configuration of a semiconductor structure of a ninth step to manufacture the split gate nonvolatile memory cell 1 according to the second embodiment. In the ninth step, the tunnel insulating film oxide film 36 to be the tunnel insulating film 8 through subsequent steps is, in the same manner as that of the eighth step in the first embodiment, formed so as to entirely cover the semiconductor structure.

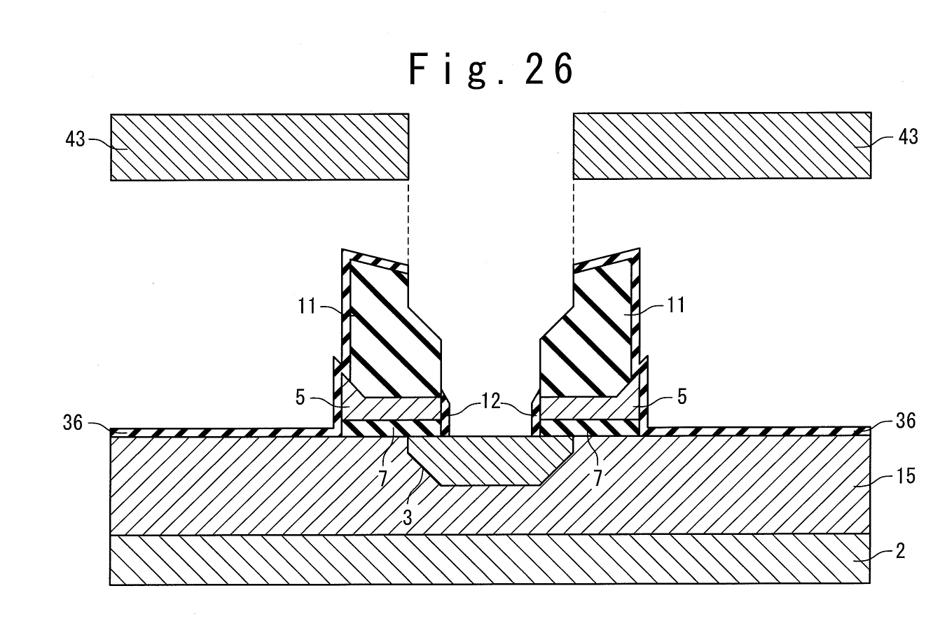

FIG. 26 is a cross-sectional view exemplifying a configuration of a semiconductor structure of a tenth step to manufacture the split gate nonvolatile memory cell 1 according to the second embodiment. In the tenth step, the tunnel insulating film oxide film 36 in the opening portion between the spacer insulating films 11 is etched by using a photoresist 43 same as the photo resist 42. Due to the etching, the side wall insulating films 12 each having a side wall shape are formed so as to cover the side surfaces of the floating gates 5.

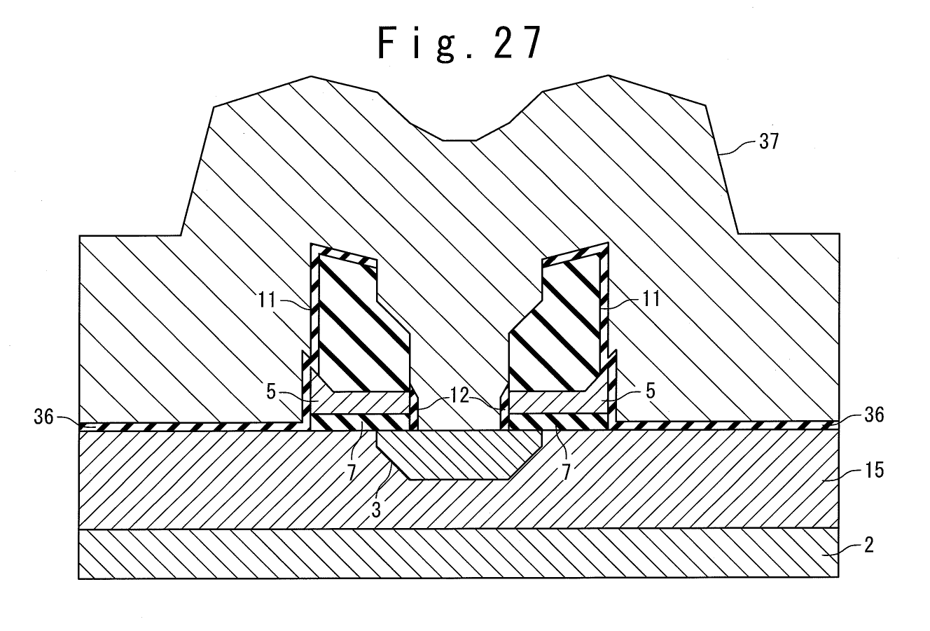

FIG. 27 is a cross-sectional view exemplifying a configuration of a semiconductor structure of an eleventh step to manufacture the split gate nonvolatile memory cell 1 according to the second embodiment. In the eleventh step, the control gate polysilicon film 37 entirely covering the semiconductor structure is formed. On this occasion, the control gate polysilicon film 37 is formed to have a sufficient film thickness required to form the control gate 6 in the subsequent step. In addition, in the eleventh step, the opening portion between the spacer insulating films 11 is filled with the control gate polysilicon film 37.

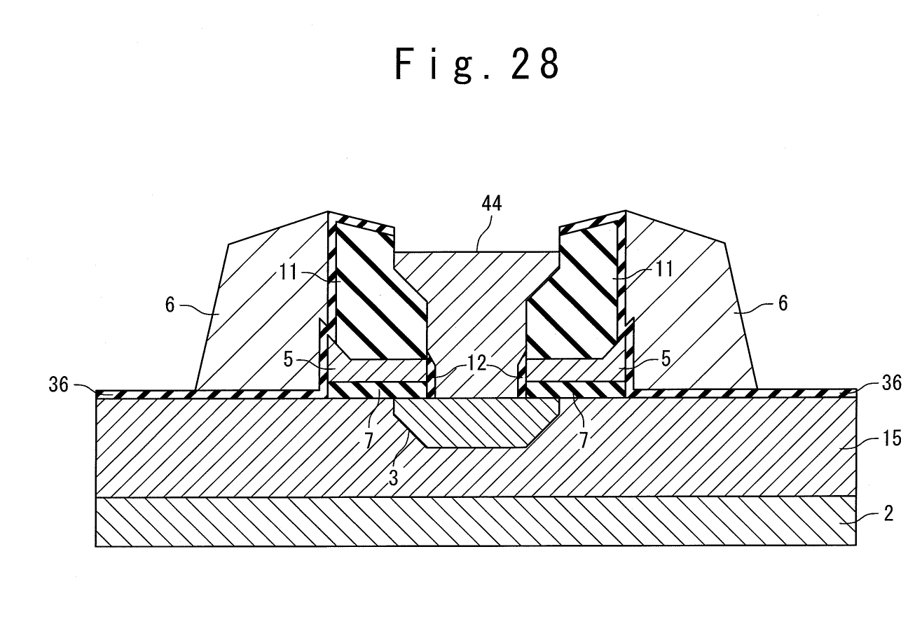

FIG. 28 is a cross-sectional view exemplifying a configuration of the semiconductor structure of a twelfth step to manufacture the split gate nonvolatile memory cell 1 according to the second embodiment. In the twelfth step, the control gates 6 each having a side wall shape are formed by etching back the control gate polysilicon film 37. On this occasion, the source plug 44 is simultaneously formed in the opening portion between the spacer insulating films 11.

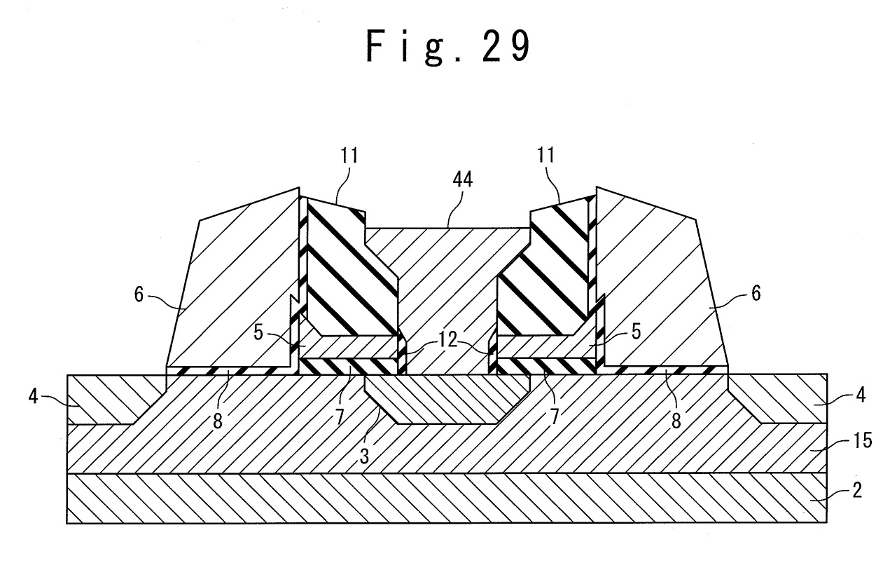

FIG. 29 is a cross-sectional view exemplifying a configuration of a semiconductor structure of a thirteenth step to manufacture the split gate nonvolatile memory cell 1 according to the second embodiment. In the thirteenth step, impurities (dopants) are implanted into the well 15 to form the second source/drain diffusion layer 4.

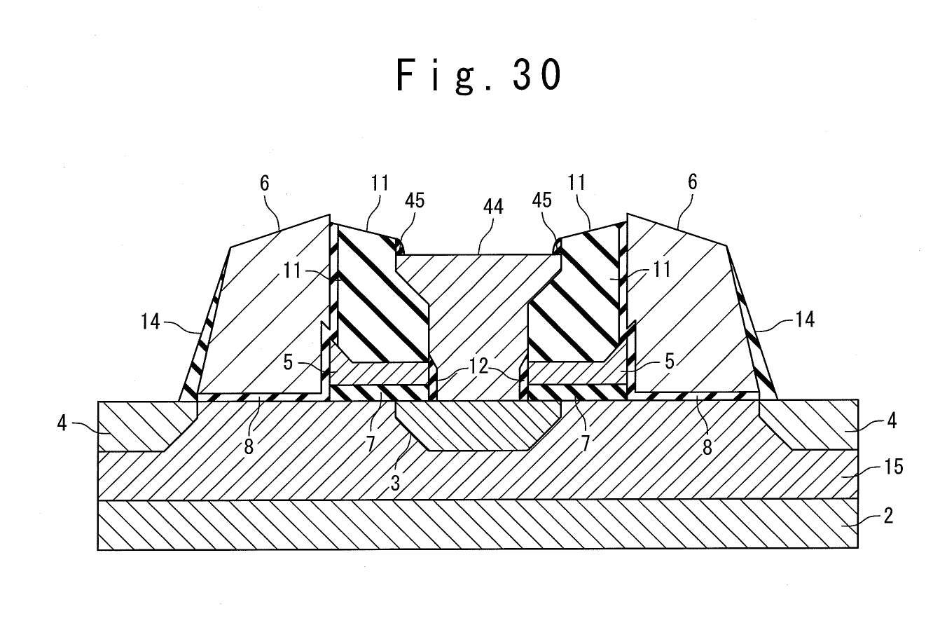

FIG. 30 is a cross-sectional view exemplifying a configuration of a semiconductor structure of a fourteenth step to manufacture the split gate nonvolatile memory cell 1 according to the second embodiment. In the fourteenth step, after the side wall oxide film 41 entirely covering the semiconductor structure has been formed, the side wall insulating films 14 are formed by etching back the side wall oxide film 41 in the manner as that of the fifteenth step according to the first embodiment. After that, the second source/drain side silicides 22, the control gate silicides 23, and the silicides 46 are formed as exemplified in the above-described FIG. 21, and thereby the split gate nonvolatile memory cell 1 according to the second embodiment is configured.

It is apparent that the present invention is not limited to the above embodiment, but may be modified and changed without departing from the scope and spirit of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A split gate nonvolatile semiconductor storage device comprising:
a substrate;
a floating gate configured to be formed on said substrate through a gate insulating film;
a control gate configured to be formed adjacent to said floating gate through a tunnel insulating film;
a first source/drain diffusion layer configured to be formed in a surface region of said substrate on a side of said floating gate;
a second source/drain diffusion layer configured to be formed in a surface region of said substrate on a side of said control gate; and
a silicide configured to contact said first source/drain diffusion layer.

2. The split gate nonvolatile semiconductor storage device according to claim 1, wherein said second source/drain diffusion layer is isolated by an insulating region from a second source/drain diffusion layer provided in an adjacent split gate nonvolatile semiconductor storage device, and
wherein said first source/drain diffusion layer is not isolated by said insulating region from a first source/drain diffusion layer provided in said adjacent split gate nonvolatile semiconductor storage device.

3. The split gate nonvolatile semiconductor storage device according to claim 1, further comprising:
a spacer insulating film configured to cover said floating gate; and
a side wall insulating film configured to cover a side wall of said floating gate,
wherein said floating gate includes:
an acute angle portion configured to be provided at an edge of a side of said control gate,
wherein said tunnel insulating film is provided between said floating gate and said control gate so as to cover said acute angle portion, and
wherein said side wall insulating film is provided on a side surface opposite to said acute angle portion of said floating gate.

4. The split gate nonvolatile semiconductor storage device according to claim 1, further comprising:
a first cell; and
a second cell,
wherein said first cell includes:
a first floating gate as said floating gate, and
a first control gate as said control gate,
said first source/drain diffusion layer, and
a third source/drain diffusion layer as said second source/drain diffusion layer,
wherein said second cell includes:
a second floating gate as said floating gate, and
a second control gates as said control gate,
said first source/drain diffusion layer, and
a fourth source/drain diffusion layer as said second source/drain diffusion layer,
wherein said first source/drain diffusion layer is shared by said first cell and said second cell, and
wherein said first cell and said second cell are symmetrical with respect to said first source/drain diffusion layer.

5. A split gate nonvolatile semiconductor storage device, comprising:
a first split gate nonvolatile memory cell; and
a second split gate nonvolatile memory cell,
wherein a source/drain diffusion layer is shared by said first split gate nonvolatile memory cell and said second split gate nonvolatile memory cell, and
wherein said first split gate nonvolatile memory cell and said second split gate nonvolatile memory cell are symmetrical with respect to said source/drain diffusion layer, and
wherein said source/drain diffusion layer directly contact a silicide.

6. A method of manufacturing a split gate nonvolatile semiconductor storage device, comprising:
forming a semiconductor structure, said semiconductor structure including:
a gate insulator formation film formed on a substrate,
a floating gate polysilicon film formed on said gate insulator formation film, and having a concave portion with a first slant portion at one end and a second slant portion at the other end,
a spacer formation insulating film formed on said floating gate polysilicon film, and having an opening portion with a first side surface extending upward from an end of said first slant portion and a second side surface extending upward from an end of said second slant portion, said opening port ion corresponding to said concave portion,
a first spacer insulating film covering said first slant portion and said first side surface, and
a second spacer insulating film covering said second slant portion and said second said surface;
removing said spacer formation insulating film without removing said first spacer insulating film and said second spacer insulating film to expose partially a surface of said floating gate polysilicon film;
removing selectively said floating gate polysilicon film and said gate insulator formation film using said first spacer insulating film and said second spacer insulating film as masks to form a floating gate with an acute portion and a gate insulating film while exposing partially said substrate;
forming a tunnel insulating film covering an exposed surface of said substrate, a side wall of said gate insulating film, and a side wall of said floating gate;
removing said tunnel insulating film between said first spacer insulating film and said second spacer insulating film to expose a surface of said substrate; and
forming a silicide between said first spacer insulating film and said second spacer insulating film.

7. The method of manufacturing a split gate nonvolatile semiconductor storage device according to claim 6, wherein said step of removing selectively said floating gate polysilicon film and said gate insulator formation film, includes:
removing said floating gate polysilicon film between said first spacer insulating film and said second spacer insulating film, and said floating gate polysilicon film outside said first spacer insulating film and said second spacer insulating film, at the same time.

8. The method of manufacturing a split gate nonvolatile semiconductor storage device according to claim 7, wherein said step of removing said tunnel insulating film, includes:
forming a control gate polysilicon film on said tunnel insulating film,
forming a control gate by etching back said control gate polysilicon film,
removing remains of said control gate polysilicon film, which remains between said first spacer insulating film and said second spacer insulating film after said control gate polysilicon film is etched back, to expose said tunnel insulating film, and
removing said exposed tunnel insulating film.

9. The method of manufacturing a split gate nonvolatile semiconductor storage device according to claim 8, wherein said step of removing said tunnel insulating film, further includes:
forming photoresist having an opening portion corresponding to a gap between said first spacer insulating film and said second spacer insulating film,
removing said control gate polysilicon film using said photoresist as a mask, and
removing said tunnel insulating film using said photoresist as a mask to expose a surface of said substrate.

10. The method of manufacturing a split gate nonvolatile semiconductor storage device according to claim 9, wherein said step of forming said silicide, includes:
forming a first side wall insulating film and a second side wall insulating film, said first side wall insulating film covering side walls of said gate insulating film and said floating gate on a side of said first spacer insulating film, and said second side wall insulating film covering side walls of said gate insulating film and said floating gate on a side of said second spacer insulating film, said first side wall insulating film and said second side wall insulating film being symmetrically arranged, and
forming said silicide between said first side wall insulating film and said second side wall insulating film.

11. The method of manufacturing a split gate nonvolatile semiconductor storage device according to claim 7, wherein said step of removing said tunnel insulating film, further includes:
forming photoresist having an opening portion corresponding to a gap between said first spacer insulating film and said second spacer insulating film,
removing said tunnel insulating film using said photoresist as a mask to expose a surface of said semiconductor substrate,
forming a control gate polysilicon film to cover surfaces of said tunnel insulating film and said semiconductor substrate, and
forming a control gate and a source plug by etching back said control gate polysilicon film.

12. The method of manufacturing a split gate nonvolatile semiconductor storage device according to claim 11, wherein said step of forming said silicide, includes:
forming said silicide on said source plug.

13. A method of manufacturing a split gate nonvolatile semiconductor storage device, comprising:
forming a first split gate nonvolatile memory cell and a second split gate nonvolatile memory cell, wherein a source/drain diffusion layer is shared by said first split gate nonvolatile memory cell and said second split gate nonvolatile memory cell, and wherein said first split gate nonvolatile memory cell and said second split gate nonvolatile memory cell are symmetrical with respect to said source/drain diffusion layer; and
forming a silicide so as to contact said source/drain diffusion layer.
